(19) United States
(12) Patent Application Publication
(10) Pub. No.: US 2015/0112617 A1
(43) Pub. Date: Apr. 23, 2015

(54) REAL-TIME MONITORING AND ANALYSIS OF ENERGY USE

(71) Applicant: Chai Energy, Los Angeles, CA (US)

(72) Inventors: Ka-Chuan SUEN, St. Louis, MO (US); J. Cole Hershkowitz, Los Angeles, CA (US)

(73) Assignee: Chai Energy, Los Angeles, CA (US)

(21) Appl. No.: 14/056,717

(22) Filed: Oct. 17, 2013

(51) Int. Cl. G01R 21/133

(52) U.S. Cl. CPC G01R 21/133
USPC 702/61

(57) ABSTRACT

A method for analyzing energy use. In some examples, energy data can be received from an energy meter, one or more energy consuming devices can be identified in the energy data, one or more insights can be generated based on at least the identification and a portion of the energy data, and information relating to at least the portion of the energy data can be generated for transmitting to a device, the generation being based on at least the one or more insights and the identification.

### FIELD OF THE DISCLOSURE

This relates generally to monitoring and analyzing energy use, and more particularly to doing so in real-time.

### BACKGROUND OF THE DISCLOSURE

Monitoring energy use of energy-consuming devices, whether electrical or otherwise, can be desirable in many circumstances. In some cases, simple knowledge of energy use can be what is desired. In other cases, knowledge of energy use can facilitate a separate goal, such as the reduction of energy use for environmental reasons, financial reasons, or otherwise.

When a single energy-consuming device—such as a refrigerator or a stove—is the only device of interest, monitoring energy use can be realized by simply monitoring the energy use of the single device by way of a single energy meter (a power meter, for example).

However, in some cases, individual energy use of multiple energy-consuming devices can be of interest; for example, a homeowner may wish to monitor appliance-specific energy use in a home, which can include energy use by a refrigerator, a stove, an oven, etc. In such a circumstance, individualized energy use for each energy-consuming device can be obtained by way of a dedicated energy meter for monitoring each device. However, providing separate energy meters for each device can be expensive and cumbersome.

### SUMMARY OF THE DISCLOSURE

The following description includes examples of monitoring and analyzing energy use of one or more energy-consuming devices using one or more energy meters. In some examples, energy data can be received from an energy meter, one or more energy-consuming devices can be identified in the energy data, one or more insights can be generated, and information relating to at least a portion of the energy data can be generated for transmitting to a device. In some examples, identifying the one or more energy-consuming devices can include a real-time process and a periodic process. In some examples, the real-time process can include identifying and classifying one or more events in the energy data. In some examples, the periodic process can include generating and associating clusters of events in the energy data. In some examples, receiving the energy data can be performed in real-time. In some examples, generating the information can be performed in real-time. In some examples, one or more parts of the real-time process can be based on one or more parts of the periodic process, and vice versa.

### BRIEF DESCRIPTION OF THE DRAWINGS

FIG. 1 illustrates an exemplary system for which the energy use monitoring and analysis of this disclosure can be implemented.

FIG. 2A illustrates an exemplary power vs. time graph for device A that can be directly measured at a node through which only device A draws power.

FIG. 2B illustrates an exemplary power vs. time graph for device B that can be directly measured at a node through which only device B draws power.

FIG. 2C illustrates an exemplary power vs. time graph for device C that can be directly measured at a node through which only device C draws power.

FIG. 2D illustrates an exemplary power vs. time graph that can be measured at a node through which devices A, B and C draw power.

FIG. 3 illustrates an exemplary system for monitoring and analyzing power data according to examples of this disclosure.

FIG. 4 illustrates an exemplary process flow for analyzing power data.

FIG. 5 illustrates an exemplary power data analysis algorithm as can be performed in the examples of this disclosure.

FIG. 6A illustrates an exemplary operation of a power data analysis algorithm with reference to a power profile, according to examples of this disclosure.

FIG. 6B illustrates an exemplary operation of a power-data analysis algorithm with reference to a histogram, according to examples of this disclosure.

FIG. 7 is a block diagram of an exemplary hardware architecture for a system implementing the power data analysis of this disclosure.

### DETAILED DESCRIPTION

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples.

Monitoring energy use of energy-consuming devices, whether electrical or otherwise, can be desirable in many circumstances. When a single energy-consuming device—such as a refrigerator or a stove—is the only device of interest, monitoring energy use can be realized by simply monitoring the energy use of the single device by way of a single power meter, for example. However, in some cases, the individual energy use of multiple energy-consuming devices can be of interest. In such a circumstance, individualized energy use for each energy-consuming device can be obtained by way of a dedicated power meter for monitoring each device. However, providing separate power meters for each device can be expensive and cumbersome. Therefore, it can be desirable to be able to determine device-specific energy use while utilizing only a single power meter in a power network, such as the utility electric meter in a home. Further, such device-specific energy use data can be analyzed, and some form of feedback can be provided to a user regarding a device-specific energy use or state (i.e., whether the device is on or off) of the user's energy-consuming devices, in an attempt to facilitate a change in the user's energy use or behavior.

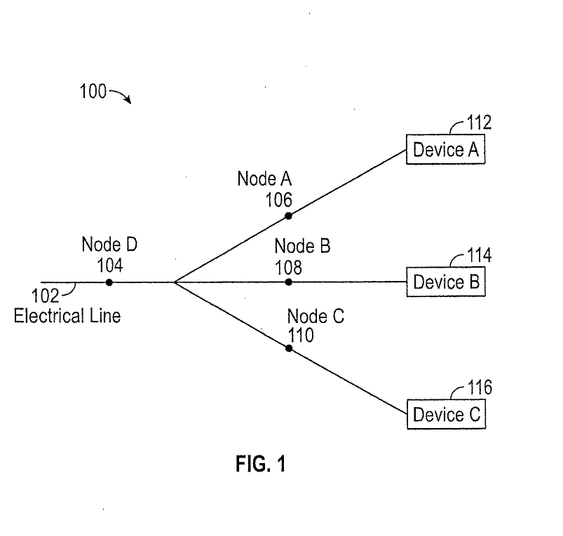

FIG. 1 illustrates an exemplary system 100 for which the energy use monitoring and analysis of this disclosure can be implemented. Electrical line 102 can supply electrical power to device A 112 through node A 106, device B 114 through node B 108 and device C 116 through node C 110. Electrical power is provided by way of example only. It is understood that the monitoring and analysis of this disclosure can be performed in the context of other types of energy use, such as natural gas use. For ease of description, however, the examples of this disclosure will be described in the context of electrical power, though it is understood that the scope of this disclosure is not so limited.

Devices A 112, B 114 and C 116 can be connected by electrical line 102 such that the devices can all draw power through node D 104. In the example illustrated, devices A 112, B 114 and C 116 can be connected in parallel by electrical line 102; however, this need not be the case, as other configurations can exist in which the devices can all draw power through node D 104. Devices A 112, B 114 and C 116 can be appliances, such as a microwave, an oven and a refrigerator in a home, for example. It is understood, however, that devices A 112, B 114 and C 116 can be any device that draws electrical power from electrical line 102, and that the devices need not be in a home or in any other type of structure.

In order to individually monitor the electrical power used by each of devices A 112, B 114 and C 116, power usage at each of nodes A 106, B 108 and C 110 can be monitored. Such monitoring can be realized by, for example, inserting a separate power meter into electrical line 102 at each of nodes A 106, B 108 and C 110. By extracting power data from each of the individual power meters described above, individualized power usage for each of devices A 112, B 114 and C 116 can be collected.

However, in some examples, inserting a power meter into existing electrical lines in existing structures, such as homes, can be difficult. Further, in addition to the difficulty, the power meters themselves can be expensive, thus providing motivation to reduce the number of power meters needed. Therefore, it can be desirable to be able to obtain individualized power use data for each of devices A 112, B 114 and C 116 with the use of a single power meter that can monitor the total power drawn through node D 104, for example.

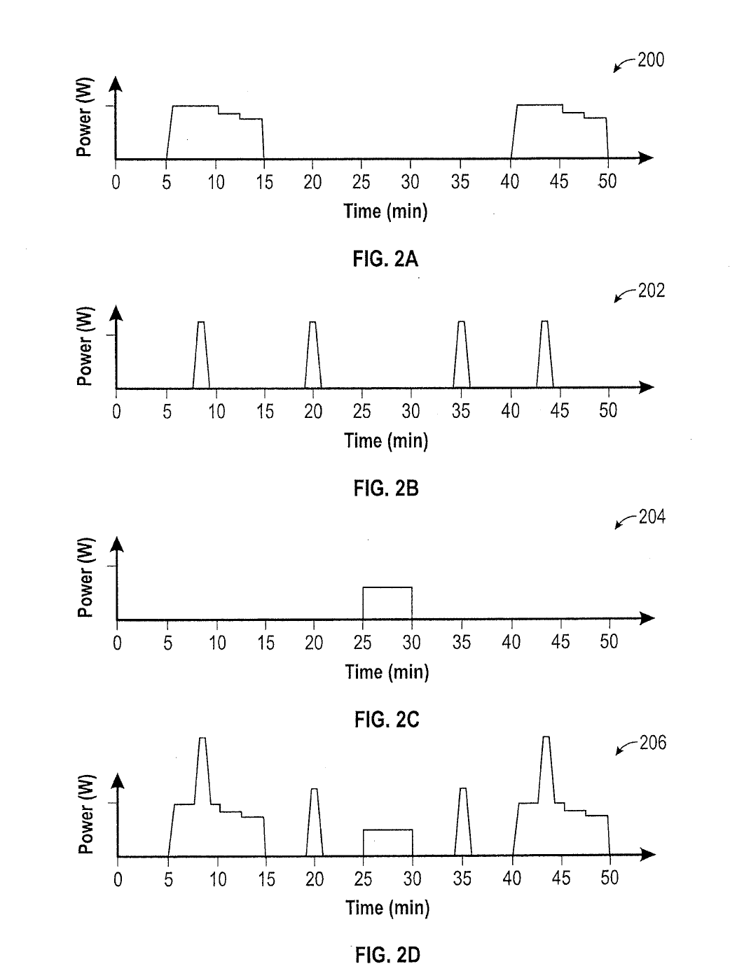

FIGS. 2A-2D show graphs that reflect exemplary power use data as a function of time according to examples of this disclosure. FIG. 2A illustrates an exemplary power vs. time graph 200 for device A 112 that can be directly measured at node A 106, for example. As is illustrated, device A 112 can start drawing power at five minutes, and can continue to draw power for ten minutes, stopping its power draw at the fifteen minute mark. During its ten minutes of drawing power, device A 112 can draw a certain amount of power for five minutes, and can exhibit a step-wise decrease in power draw during the next five minutes. Device A 112 can exhibit a similar power profile starting at the 40 minute mark as well. It is understood that the power vs. time graphs are provided by way of example only, and that the devices in the examples of this disclosure can have different power vs. time graphs than the ones illustrated.

FIG. 2B illustrates an exemplary power vs. time graph 202 for device B 114 that can be directly measured at node B 108, for example. Device B 114 can exhibit the power vs. time profile as illustrated, and can be interpreted similarly as described above with respect to FIG. 2A. FIG. 2C illustrates an exemplary power vs. time graph 204 for device C 116 that can be directly measured at node C 110, for example. Device C 116 can exhibit the power vs. time profile as illustrated, and can also be interpreted similarly as described above with respect to FIG. 2A.

As stated above, it can be desirable to extract and analyze power profiles for individual devices—such as the power profiles for devices A 112, B 114 and C 116 in FIGS. 2A, 2B and 2C, respectively—from a single power measurement site, such as at node D 104. FIG. 2D illustrates an exemplary power vs. time graph 206 that can be measured at node D 104, for example. Assuming that devices A 112, B 114 and C 116 have the power profiles as illustrated in FIGS. 2A-2C, the devices' combined power profile, as can be measured at node D 104, can be as illustrated in graph 206. As can be seen, graph 206 can be a combination of graphs 200, 202 and 204.

In some examples, power data, such as that in graph 206, can be processed in order to identify and/or reconstruct individualized power data, such as the power data represented in graphs 200, 202 and 204. Exemplary systems and methods for such power data processing will be described below.

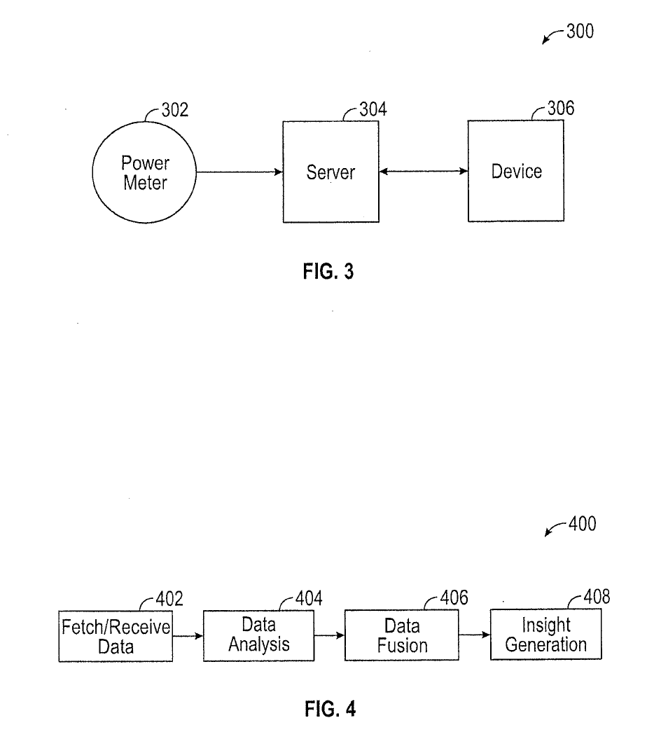

FIG. 3 illustrates an exemplary system 300 for monitoring and analyzing power data according to examples of this disclosure. Power meter 302 can collect power data, as described above. For example, power meter 302 can monitor power use at node D 104, and can collect a power profile as in graph 206, for example. Power meter 302 can be any type of power meter, including a smart meter that can be connected to a home, and can monitor the total power use of the home, for example. It is understood, however, that power meter 302 need not measure the power use of a home, or any structure, but can be any power meter that may measure power use of one or more power-consuming devices.

Power meter 302 can include an interface for transmitting collected power data to an external device. In some examples, the interface can be a wired interface, such as a network interface. In some examples, the interface can be a wireless interface, such as a Zigbee radio. Any interface for transmitting collected power data can be utilized in power meter 302. Further, in some examples, power meter 302 can be integrated with server 304 and/or device 306 in a single device, such that the power meter may not need to transmit collected power data to an external device. In such a circumstance, communications between the power meter, server and/or device components of the composite device can occur internally within the composite device. For ease of description, however, the examples of this disclosure will be described assuming power meter 302, server 304 and device 306 are separate devices.

Power data collected by power meter 302 can be transmitted to server 304 via an appropriate interface, as described above. If power meter 302 includes a Zigbee radio, transmission to server 304 can take place from the Zigbee radio to a Zigbee gateway that can be connected to the internet, for example. The Zigbee gateway can be connected to the internet via any appropriate connection; for example, a wired connection, such as Ethernet, or a wireless connection, such as Wi-Fi. The Zigbee gateway can then transmit the power data received from power meter's 302 Zigbee radio to server 304 via the internet.

Server 304 can receive and analyze the power data. In some examples, the reception and analysis can be in real-time, though it need not be. Exemplary details of processes that can take place on server 304 will be described later.

Based on its analysis of the power data received from power meter 302, server 304 can transmit information to device 306. Device 306 can be any device that can receive information from server 304, such as a user's mobile telephone or a computer. The information transmitted to device 306 can be information that can be generated based on the power data, such as information that a specific appliance in a user's home has been on longer than it should. Exemplary details about the generation and the content of the above information will be described later.

The information, and its transmission to a user via device 306, can be designed to attempt to change a user's power use-related behavior. For example, server 304 can transmit a message to device 306 that informs a user that the user's air conditioning unit is on, and that it need not be on because the weather outside is cool. This information can be designed to motivate the user to turn off the user's air conditioning unit.

FIG. 4 illustrates an exemplary process flow 400 for analyzing power data. In some examples, server 304 can receive power data at step 402. The power data can be received from any source that can transmit power data to server 304; for example, power meter 302. As stated above, the power data can be received in real-time, though it need not be. In some examples, the power data can be received in intervals of time, for example.

The power data can be analyzed in step 404. The analysis can be performed in real-time, though it need not be. The analysis can result in the identification of one or more power-consuming devices that consume at least some power in the power data being analyzed. The analysis can also result in the generation of information related to the one or more power-consuming devices. For example, in some examples, it can be determined when one or more of the devices are on or off, and/or how much power one or more of the devices use when on. It is understood that the above generated information is given by way of example only, and does not limit the scope of this disclosure; no such information need be generated, and in some examples, different types of information can be generated in addition to, or instead of, the examples given above. Exemplary details of step 404 will be described in more detail below.

The above determinations (i.e., outputs) from step 404 can be fused with various types of data in step 406 such that the fused data can be helpful to a user; for example, a homeowner. In some examples, the outputs from step 404 can be fused with one or more of weather data, data relating to local events, data about whether a user is home or not, data about how many people are in the user's house, data about the location of the user's house, data about the appliance models in the user's house, data about the construction of the user's house, data about one or more operating states of appliances in the user's house, and/or data about the user's neighbors/neighborhood, for example. Any data that might be helpful to the user can be fused with the outputs in step 406.

The fused data from step 406 can be analyzed, and “insights” can be generated based on the fused data in step 408. The generated “insights” can be any insight about a user's power use and/or the state(s) of the user's power-consuming devices, and can be at least partially based on data that was fused in step 406. For example, an insight can be a message to the user to turn off their air conditioning unit because it is currently on and the weather outside is cool. As another example, an insight can be a message to the user that they should buy a new refrigerator because, based on its power use, the refrigerator appears to be old. It is understood that other insights are possible and are similarly within the scope of this disclosure. For example, an insight might tell the user that they left their stove on when they left their home, that they use their dishwasher and charge their electric vehicle during peak electricity rate times and should consider shifting these activities to off-peak times, or that their washing machine has completed its cycle and that the user should consider moving their clothes to the dryer. The above insights need not be directed to a specific user in the form of a message. Rather, such insights can be generated and recorded without sending a message to a user; for example, the insights can be stored internally on server 304, or information about the insights can be communicated to a user in ways other than a message.

The insights described above can be generated in step 408 based on one or more defined rules. In some examples, the rules can be absolute or rigid, such as absolute if-then statements. For example, a rule can state that if an air conditioning unit is on and the temperature outside is less than 68° F., then an insight should be generated informing a user to turn off their air conditioning unit. In some examples, the rules can be more probabilistic. In some examples, the rules can be adaptive based on a feedback system. In some examples, users can generate their own rules for generating insights. For example, a user can define a rule that will generate a message for the user if the user's television is on between four and five o'clock in the afternoon, which can inform the user that the user's children are home.

The above insights can be generated in real-time (i.e., as power data is received and analyzed), though they need not be. In any case, in some examples, the generated insights can be sent to a user's device, for example, a user's phone, in the form of a message.

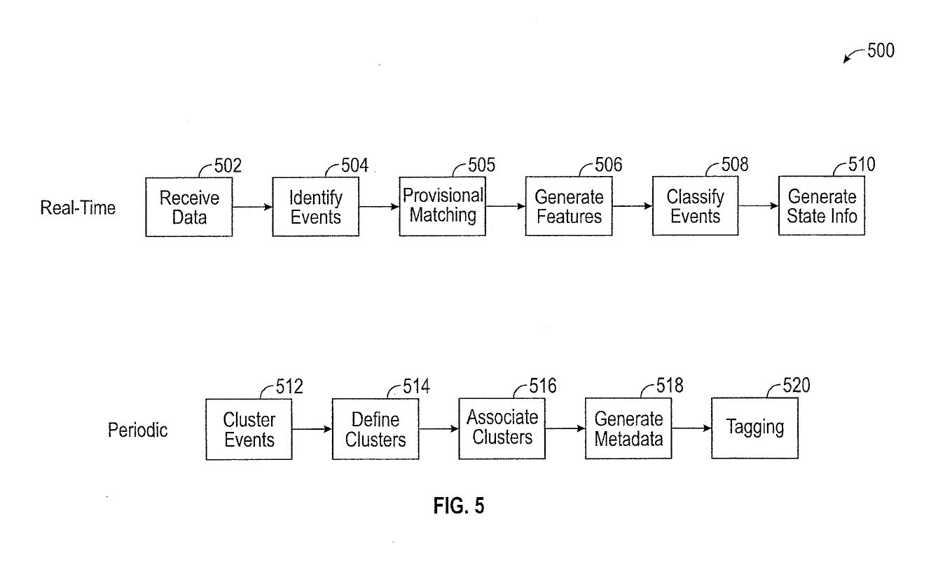

FIG. 5 illustrates an exemplary power data analysis algorithm 500 as can be performed in data analysis step 404. Power data analysis algorithm 500 can include one or more steps that can be performed in real-time (i.e., one or more real-time processes) and one or more steps that can run periodically (i.e., one or more periodic processes). Although power data analysis algorithm 500 will be described as having specific real-time steps and periodic steps, it is understood that variations from the following description are also within the scope of this disclosure. For example, some or all of the real-time steps can instead be performed periodically, and/or some or all of the periodic steps can instead be performed in real-time. For ease of description, however, the steps will be described as illustrated in FIG. 5.

The real-time steps can begin with receiving power data at step 502. Power data can be received as described with reference to FIG. 3, for example.

Events can be identified in the power data in step 504. An event can be defined as any change in power use in which the power use changes in a relevant way. For example, an event can be a change in a metric of interest that is greater or less than a specified amount. In some examples, the metric of interest can be power use, and therefore an event can be a change in power use that is greater than a specified amount (e.g., greater than a 50 W change in power use). In some examples, the metric of interest can be the slope of the power use profile, and an event can be a change in power use that has a slope that is greater than a specified amount. Identifying and working with events, as will be described below, as opposed to the power data itself, can allow for a reduction in the amount of data that may need to be processed in other steps of power data analysis algorithm 500. This reduction can allow for the steps described herein to be performed more efficiently than they might otherwise be, and in some examples, to be performed in real-time.

The events identified in the power data in step 504 can be provisionally matched with each other in step 505. This provisional matching can be performed in real-time, though it need not be. Provisional matching can be the pairing of two events that can be related to each other in a relevant way. For example, an event in which a power-consuming device has been turned on (i.e., an “on” event) can be matched with an event in which the power-consuming device has been turned off (i.e., an “off” event). The above-mentioned “on” event can be, for example, an upward spike in power use, and the above-mentioned “off” event can be, for example, a downward reduction in power use.

Although provisional matching has been described as pairing two events, in some examples, more than two events can be matched with each other. For example, a power-consuming device can have different power states (e.g., full power, half power, off) that can produce different events in the power profile; these events can be provisionally matched with each other as belonging to the same power-consuming device. For ease of description, however, the examples of this disclosure will be described as matching or pairing only two events and/or clusters (clusters will be described later). It is understood that matching or pairing of more than two events and/or clusters is also within the scope of this disclosure.

In some examples, the provisional matching in step 505 can be realized by matching events based on one or more of the metrics used to identify the events in step 504. For example, if change in power use is used as a metric in step 504 to identify events, a provisional match between two events can be determined to exist when a net change in power use between the two events sums to approximately zero; in other words, when a positive change in power use of one event has the same or similar magnitude as a negative change in power use of another event. In some examples, one or more different metrics, in addition to change in power use, can be used to provisionally match events. In some examples, one or metrics other than change in power use can be used to provisionally match events. The provisional matching performed in step 505 can be utilized in other steps of power data analysis algorithm 500, as will be described later.

In step 506, features can be generated for, and associated with, one or more of the events identified above. The generated features can be one or more quantities such as a change in power use associated with an event, a slope of a change in power use associated with an event, a maximum change in the power use associated with an event, a duration of a change in power use, noise that can exist in a power profile after an event, noise that can exist in a power profile before an event, a difference in noise that can exist in a power profile before and after an event, a time of day at which an event occurred, a day of the year during which an event occurred, a season of the year in which an event occurred and/or whether an event occurred on a weekday or a weekend day. Further, one or more features can be generated for the events based on the provisional matching that can be performed in step 505. For example, the generated features can be one or more quantities such as a duration of a matched event pair (i.e., how much time separates the matched events), the features of another event with which a particular event is matched, the total power used by the matched events, and/or a number of events within a time encompassed by the matched events.

One or more of the events identified above can be classified in step 508. Classification of an event can be the association of an event with a cluster into which the event “fits” based on the generated features of the event. The cluster mentioned above can be one of one or more clusters of events that can be generated in the periodic portion of power data analysis algorithm 500, the exemplary details of which will be described later. Whether an event “fits” into a cluster can be determined by comparing one or more of the generated features of the event (i.e., the features generated in step 506) with one or more features of the cluster. If the compared one or more features sufficiently match, the event at issue can be said to “fit” into the cluster at issue. In some examples, an event can fit into multiple clusters. In some examples, the most likely cluster into which an event fits can be selected as the cluster into which the event fits. In some examples, if a probability that an event fits into a cluster is below a certain threshold, no cluster can be associated with the event. In some examples, a cluster can be associated with an event in real-time, and the association can be final (i.e., the association may not be changed in the future). In some examples, an association of a cluster with an event can be made, but the association can be held open (i.e., the association can be non-final), and the association can be changed later if a different association becomes more likely to be the correct association of a cluster with the event. In some examples, a cluster can be associated with an event in a probabilistic way (e.g., there is a 60% likelihood that the cluster should be associated with this event).

In some examples, as will be described later, the clusters that can be generated in the periodic portion of power data analysis algorithm 500 can be associated with each other (i.e., matched or paired with each other). This association of clusters can be utilized in step 508 to facilitate the association of matched events with matched clusters. For example, if two clusters have been associated with each other in the periodic portion of power data analysis algorithm 500, two matched events that fit into those two clusters can be associated with the two clusters in step 508.

State information can be generated for each matched pair of events in step 510. State information can be information about the power data encompassed by each event pair that may be matched in steps 505 and 508. For example, state information can be information about an amount of power used during the time between matched events, and/or information about a length of time that can separate the matched events. In some examples, other state information can additionally or alternatively be generated in step 510. In some examples, the generated state information can be any information that can be helpful in analyzing and/or understanding the power data; for example, information that can be helpful to a homeowner. Such information could be, for example, a time of the day that the power was used by the matched pair of events.

As mentioned above, power data analysis algorithm 500 can have a portion that can be run periodically in addition to a portion that can be run in real-time. The periodic portion can include steps 512, 514, 516, 518 and 520, as illustrated in FIG. 5.

Events that have been identified in step 504, described above, can be clustered in step 512. The events can be events from a specified time period, such as events that have occurred over the past month or the past year. Events can be clustered based on one or more of the features generated for the events in step 506. In particular, events can be clustered with other events that share one or more similar features. For example, if features generated in step 506 for the events to be clustered include “change in power,” “maximum power,” and “time of day,” events can be clustered in step 512 based on one or more of the features: “change in power,” “maximum power,” and “time of day.” In other words, one or more clusters of events can be created for each feature to be clustered by, where events with similar values for the particular feature can be grouped together in a single cluster. For example, for the feature “change in power,” one or more clusters, each containing events with different changes in power, can be created (e.g., a cluster in which the events exhibit a change in power of 500 W, a cluster in which the events exhibit a change in power of 20 W, etc.). One or more of such clusters can similarly be created based on one or more of the remaining features, i.e., “maximum power” and “time of day.” Clustering events in this way can allow for a determination as to how many times an event exhibiting a specified feature has occurred during a time period of interest, and/or how common such events may be.

It is understood that the above clusters need not be rigidly defined, though in some examples they may be. Rather, in some examples, the clusters can include events that may not strictly exhibit the value of the feature being clustered, but may nonetheless deviate from the value of the feature in a statistically insignificant manner. For example, a cluster of events that exhibit a change in power of 500 W may include events that exhibit a change in power of 497 W or 505 W or the like. By clustering in such a manner, noise that may exist in the power data can be filtered out and effectively removed from other processing that may take place in power data analysis algorithm 500. The above-referenced noise can be intrinsic noise (i.e., noise that does reflect actual power use, for example, a refrigerator using a little more or a little less power on one day compared with another day because of, for example, ambient temperature differences on those days) or can be extrinsic noise (i.e., noise that does not reflect actual power use, for example, noise that can be introduced by power lines in the signal path of the power data).

One or more of the clusters can be defined in step 514. Specifically, each cluster can be defined by one or more of the features of the events that constitute the cluster. For example, a cluster in which the constituting events exhibit a change in power of approximately 500 W, and tend to occur in the summer and at any time of the day, can be defined as such. In particular, such a cluster might be defined as follows: the events in this cluster exhibit a change in power of 500 W+/−20 W, the events in this cluster tend to occur at any time of the day, and the events in this cluster tend to occur in the summer. As is apparent from the discussion above, one or more of the above definitions can be probabilistic definitions (i.e., any single event in the cluster can fall outside of the created definition, but as a group, the events can tend to satisfy the created definition). In some examples, one or more of the definitions can be absolute (i.e., no event in the cluster can fall outside of the created definition). Each time the above clustering 512 and defining 514 steps are performed, the clusters can become better formed, and the performance of power data analysis algorithm 500 can improve.

Clusters can be associated with one another in step 516. In particular, in some examples, two clusters whose events tend to happen together can be associated with one another. In some examples, if events in the clusters tend to happen together, then the events in the clusters can be associated with the same power-consuming device (e.g., one cluster of events can be the turning “on” of the device, and the other cluster of events can be the turning “off” of the device). As stated above, in some examples, more than two clusters can be associated with one another. However, for ease of description, the examples of this disclosure will be described as associating two clusters with one another. The association of clusters can be absolute (e.g., the two or more clusters at issue must be associated), or it can be probabilistic (e.g., there is a 70% likelihood that the two or more clusters at issue should be associated).

In some examples, events in clusters can “tend to happen together” if for example, the events tend to occur in close time-proximity with one another, or the events which constitute the clusters tend to exhibit similar, but opposite, changes in power, or both. The scope of this disclosure also extends to other ways that events can “tend to happen together” that similarly provide the desired associations of clusters in step 516 (i.e., associations of clusters of events that belong to the same power-consuming device, such as an “on” cluster and a corresponding “off” cluster).

The association in step 516 can additionally or alternatively be based on the provisional matching of events that can occur in step 505 of the real-time portion of power data analysis algorithm 500. For example, if two events in two clusters have been provisionally matched in step 505, the fact of their matching can be a factor in determining whether to associate the two clusters in which the events reside in step 516.

Metadata can be generated for each pair of clustered events in step 518. The generated metadata can be any information that can be helpful in determining what power-consuming device the pair of clustered events corresponds to. For example, a pair of clustered events can be determined to occur nine times per day, but only when the weather is hot. This information can be generated as metadata for the pair of clustered events at issue. It is understood that the generation of other types of metadata is similarly within the scope of this disclosure.

In some examples, based on the above metadata, it can be possible to identify what power-consuming device a pair of clustered events corresponds to. For example, in the case of a pair of clustered events that occur nine times per day, but only when the weather outside is hot, it can be likely that the pair of clustered events corresponds to an air conditioning unit; the pair of clustered events can then be identified as such. Identifications of other power-consuming devices can similarly be made at this stage. As should be apparent from this disclosure, the identification of a pair of clustered events can be absolute (e.g., this pair of clustered events corresponds to a dishwasher) or probabilistic (e.g., there is a 75% likelihood that this pair of clustered events corresponds to a dishwasher).

In some examples, a user can change an identification of a pair of clustered events that may have been made above. In some examples, a user can provide an identification in the first instance for a pair of clustered events for which an identification could not previously be made. The tagging of pairs of clustered events with their corresponding power-consuming devices can be done in step 520. Such tagging can be performed periodically, as is illustrated in FIG. 5, although it is understood that it need not be. The user can tag pairs of clustered events using any appropriate means, such as a mobile device, a computer, a user-interface on a server, or any other means for providing input to power data analysis algorithm 500.

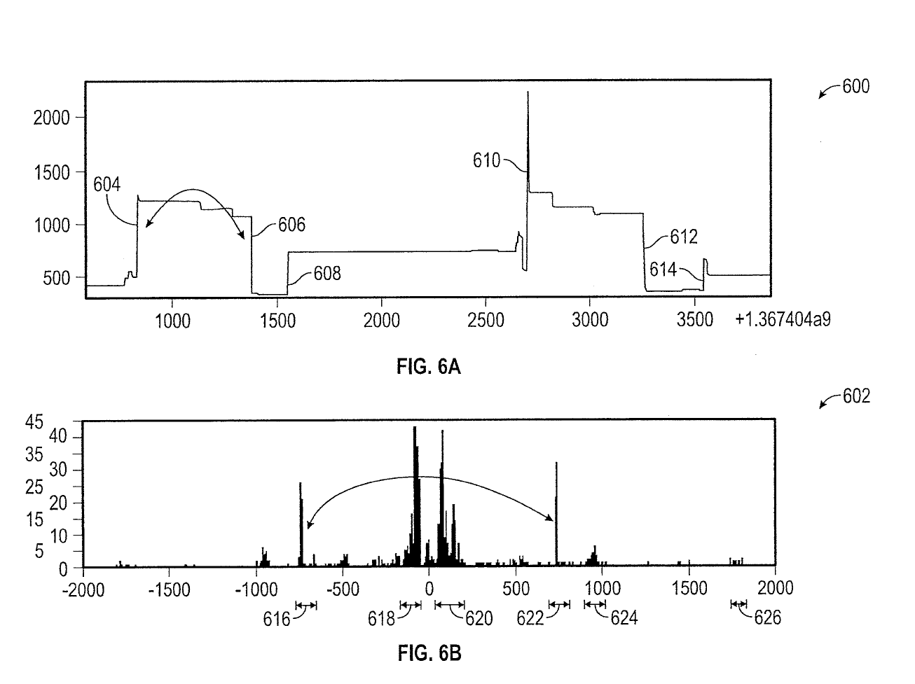

Exemplary operation of power data analysis algorithm 500 will now be further described with reference to FIGS. 6A-6B. FIG. 6A illustrates an exemplary operation of power data analysis algorithm 500 with reference to power profile 600, according to examples of this disclosure. FIG. 6B illustrates an exemplary operation of power-data analysis algorithm 500 with reference to histogram 602, according to examples of this disclosure. Histogram 602 can provide a visual representation of the number of events that have occurred (along the vertical axis) during a specified period of time as a function of one or more values of a feature of interest (along the horizontal axis); the more events that have occurred with a particular feature value, the higher the peak that can exist at that feature value in the histogram. The following description will be provided in a manner that alternates between the real-time and the periodic portions of power data analysis algorithm 500; it is understood that the order in which the following description is provided does not necessarily limit the power data analysis algorithm to the order described.

Power profile 600 can be a collection of the power data received as described above with reference to step 502, for example. As described above, the power data can be received in real-time, though it need not be.

Events 604, 606, 608, 610, 612 and 614 can be identified in step 504. The events can be identified as described above with reference to step 504.

Some or all of the events can be provisionally matched with each other in step 505. For example, events 604 and 606 can be provisionally matched with each other, as described above. In some examples, events 604 and 606 can be provisionally matched with each other because they may exhibit a net change in power of approximately zero, for example. In some examples, the provisional matching can be based on other criteria. The provisional matching can be performed as described above with reference to step 505.

Features can be generated for one or more of events 604, 606, 608, 610, 612 and 614 in step 506. The features can be generated as described above with reference to step 506.

Events can be periodically clustered in step 512, as illustrated in FIG. 6B. For example, in some examples, clusters 616, 618, 620, 622, 624 and 626 can be defined as clusters of events because they share one or more characteristics of interest. The clusters of events can be defined as described above with reference to step 514.

Events 604, 606, 608, 610, 612 and 614 can be classified in step 508 based on the clusters defined in step 514 (and as illustrated in FIG. 6B). For example, event 604 can be classified as being associated with cluster 622, and event 606 can be classified as being associated with cluster 616. The remaining events can similarly be classified. The classification of events can be performed as described above with reference to step 508.

Clusters 616, 618, 620, 622, 624 and 626 can be associated with one another in step 516. For example, clusters 622 and 616 can be associated with each other. Because of this association, events 604 and 606, which can be associated with clusters 622 and 616, respectively, can also be associated with each other (as a result of the association of the clusters in which they reside). The association can be performed as described above with reference to step 516.

State information can be generated for each pair of events in step 510. For example, state information can be generated for the event 604 and 606 event pair. State information can be generated as described above with reference to step 510.

Metadata can be generated for each pair of clustered events in step 518. For example, metadata can be generated for paired clusters 616 and 622. Metadata can be generated as described above with reference to step 518.

Pairs of clusters can be tagged with corresponding power-consuming devices (e.g., appliances) in step 520. For example, paired clusters 616 and 622 can be tagged as corresponding to an air conditioning unit. Tagging, whether by the system or a user, can be performed as described above with reference to steps 518 and 520.

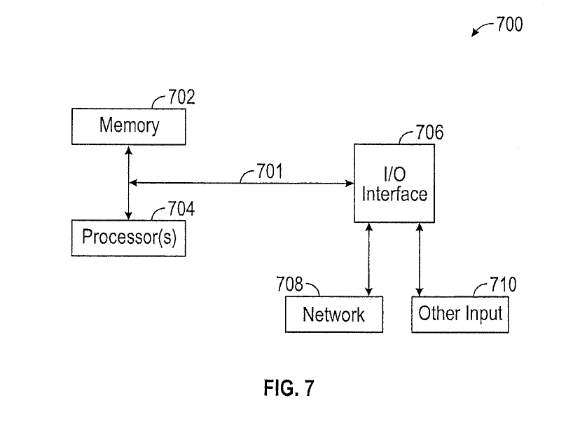

FIG. 7 is a block diagram of exemplary hardware architecture 700 for a system implementing the power data analysis of this disclosure. The system can include memory 702, one or more processors 704 and I/O interface 706. Memory 702, one or more processors 704 and/or I/O interface 706 can be separate components or can be integrated circuits. The various components in the system can be coupled by one or more communication buses or signal lines 701.

I/O interface 706 can be coupled to a network 708. I/O interface 706, through network 708, can send and/or receive data from and/or to the system. Other input 710 can also be coupled to I/O interface 706, and can allow for sending and/or receiving of data from and/or to the system other than via network 708.

Memory 702 can include random access memory and/or non-volatile memory. For example, memory 702 can include one or more magnetic disk storage devices, one or more optical storage devices, and/or flash memory. Memory 702 can store various instructions for performing some or all aspects of the power data analysis of this disclosure.

Various functions of system 700 may be implemented in hardware and/or in software, including in one or more signal processing and/or application specific integrated circuits. The features described in this disclosure can be implemented in digital electronic circuitry, or in computer hardware, firmware, software, or in combinations of them. The features can be implemented in a computer program product tangibly embodied in an information medium, e.g., in a computer-readable storage medium, for execution by a processor; method steps can be performed by a processor executing a program of instructions to perform functions of the described examples.

The described features can be implemented in one or more computer programs that are executable on a programmable system including at least one processor coupled to receive data and instructions from, and to transmit data and instructions to, a data storage system, at least one input device, and at least one output device. Suitable processors for the execution of a program of instructions include, by way of example, both general and special purpose microprocessors, and the sole processor or one of multiple processors or cores, of any kind of computer. Generally, a processor can receive instructions and data from a read-only memory or a random access memory or both. Generally, a computer can also include, or be operatively coupled to communicate with, one or more storage devices for storing data files; such devices can include magnetic disks, such as internal hard disks and removable disks; magneto-optical disks; and optical disks. Storage devices suitable for tangibly embodying computer program instructions and data can include all forms of non-volatile memory; magnetic disks such as internal hard disks and removable disks; magneto-optical disks; and CD-ROM and DVD-ROM disks. The processor and the memory can be supplemented by, or incorporated in, ASICs (application specific integrated circuits).

Therefore, according to the above, some examples of the disclosure are directed to a method comprising receiving energy data from an energy meter, identifying one or more energy-consuming devices in the energy data, generating one or more insights based on at least the identification and a portion of the energy data, and generating information, for transmitting to a device, relating to at least the portion of the energy data, the generation being based on at least the one or more insights and the identification. Additionally or alternatively to one or more of the examples disclosed above, in some examples, identifying the one or more energy-consuming devices comprises a real-time process, and a periodic process. Additionally or alternatively to one or more of the examples disclosed above, in some examples, the real-time process comprises identifying one or more events in the energy data, and classifying the one or more events. Additionally or alternatively to one or more of the examples disclosed above, in some examples, the periodic process comprises generating one or more clusters of one or more events in the energy data, and associating a first of the clusters with a second of the clusters. Additionally or alternatively to one or more of the examples disclosed above, in some examples, receiving the energy data comprises receiving the energy data in real-time. Additionally or alternatively to one or more of the examples disclosed above, in some examples, generating the information comprises generating the information in real-time. Additionally or alternatively to one or more of the examples disclosed above, in some examples, classifying the one or more events comprises classifying the one or more events based at least on a portion of the periodic process.

Some examples of the disclosure are directed to a non-transitory computer-readable storage medium having stored therein instructions, which when executed by an apparatus, cause the apparatus to perform a method comprising receiving energy data from an energy meter, identifying one or more energy-consuming devices in the energy data, generating one or more insights based on at least the identification and a portion of the energy data, and generating information, for transmitting to a device, relating to at least the portion of the energy data, the generation being based on at least the one or more insights and the identification. Additionally or alternatively to one or more of the examples disclosed above, in some examples, identifying the one or more energy-consuming devices comprises a real-time process, and a periodic process. Additionally or alternatively to one or more of the examples disclosed above, in some examples, the real-time process comprises identifying one or more events in the energy data, and classifying the one or more events. Additionally or alternatively to one or more of the examples disclosed above, in some examples, the periodic process comprises generating one or more clusters of one or more events in the energy data, and associating a first of the clusters with a second of the clusters. Additionally or alternatively to one or more of the examples disclosed above, in some examples, receiving the energy data comprises receiving the energy data in real-time. Additionally or alternatively to one or more of the examples disclosed above, in some examples, generating the information comprises generating the information in real-time. Additionally or alternatively to one or more of the examples disclosed above, in some examples, classifying the one or more events comprises classifying the one or more events based at least on a portion of the periodic process.

Some examples of the disclosure are directed to an apparatus, comprising a processor to execute instructions, and a memory coupled with the processor to store instructions, which when executed by the processor, cause the processor to perform a method comprising receiving energy data from an energy meter, identifying one or more energy-consuming devices in the energy data, generating one or more insights based on at least the identification and a portion of the energy data, and generating information, for transmitting to a device, relating to at least the portion of the energy data, the generation being based on at least the one or more insights and the identification. Additionally or alternatively to one or more of the examples disclosed above, in some examples, identifying the one or more energy-consuming devices comprises a real-time process, and a periodic process. Additionally or alternatively to one or more of the examples disclosed above, in some examples, the real-time process comprises identifying one or more events in the energy data, and classifying the one or more events. Additionally or alternatively to one or more of the examples disclosed above, in some examples, the periodic process comprises generating one or more clusters of one or more events in the energy data, and associating a first of the clusters with a second of the clusters. Additionally or alternatively to one or more of the examples disclosed above, in some examples, receiving the energy data comprises receiving the energy data in real-time. Additionally or alternatively to one or more of the examples disclosed above, in some examples, generating the information comprises generating the information in real-time. Additionally or alternatively to one or more of the examples disclosed above, in some examples, classifying the one or more events comprises classifying the one or more events based at least on a portion of the periodic process.

Although examples of this disclosure have been fully described with reference to the accompanying drawings, it is to be noted that various changes and modifications will become apparent to those skilled in the art. Such changes and modifications are to be understood as being included within the scope of examples of this disclosure as defined by the appended claims.

1. A method comprising:
receiving energy data from an energy meter;
identifying one or more energy-consuming devices in the energy data;
generating one or more insights based on at least the identification and a portion of the energy data; and
generating information, for transmitting to a device, relating to at least the portion of the energy data, the generation being based on at least the one or more insights and the identification.

2. The method of claim 1, wherein identifying the one or more energy-consuming devices comprises:
a real-time process; and
a periodic process.

3. The method of claim 2, wherein the real-time process comprises:
identifying one or more events in the energy data; and
classifying the one or more events.

4. The method of claim 2, wherein the periodic process comprises:
generating one or more clusters of one or more events in the energy data; and
associating a first of the clusters with a second of the clusters.

5. The method of claim 1, wherein receiving the energy data comprises receiving the energy data in real-time.

6. The method of claim 5, wherein generating the information comprises generating the information in real-time.

7. The method of claim 3, wherein classifying the one or more events comprises classifying the one or more events based at least on a portion of the periodic process.

8. A non-transitory computer-readable storage medium having stored therein instructions, which when executed by an apparatus, cause the apparatus to perform a method comprising:
receiving energy data from an energy meter;
identifying one or more energy-consuming devices in the energy data;
generating one or more insights based on at least the identification and a portion of the energy data; and
generating information, for transmitting to a device, relating to at least the portion of the energy data, the generation being based on at least the one or more insights and the identification.

9. The computer-readable storage medium of claim 8, wherein identifying the one or more energy-consuming devices comprises:
a real-time process; and
a periodic process.

10. The computer-readable storage medium of claim 9, wherein the real-time process comprises:
identifying one or more events in the energy data; and
classifying the one or more events.

11. The computer-readable storage medium of claim 9, wherein the periodic process comprises:
generating one or more clusters of one or more events in the energy data; and
associating a first of the clusters with a second of the clusters.

12. The computer-readable storage medium of claim 8, wherein receiving the energy data comprises receiving the energy data in real-time.

13. The computer-readable storage medium of claim 12, wherein generating the information comprises generating the information in real-time.

14. The computer-readable storage medium of claim 10, wherein classifying the one or more events comprises classifying the one or more events based at least on a portion of the periodic process.

15. An apparatus, comprising:
a processor to execute instructions; and
a memory coupled with the processor to store instructions, which when executed by the processor, cause the processor to perform a method comprising:
receiving energy data from an energy meter;
identifying one or more energy-consuming devices in the energy data;
generating one or more insights based on at least the identification and a portion of the energy data; and
generating information, for transmitting to a device, relating to at least the portion of the energy data, the generation being based on at least the one or more insights and the identification.

16. The apparatus of claim 15, wherein identifying the one or more energy-consuming devices comprises:
a real-time process; and
a periodic process.

17. The apparatus of claim 16, wherein the real-time process comprises:
identifying one or more events in the energy data; and
classifying the one or more events.

18. The apparatus of claim 16, wherein the periodic process comprises:
generating one or more clusters of one or more events in the energy data; and
associating a first of the clusters with a second of the clusters.

19. The apparatus of claim 15, wherein receiving the energy data comprises receiving the energy data in real-time.

20. The apparatus of claim 19, wherein generating the information comprises generating the information in real-time.

21. The apparatus of claim 17, wherein classifying the one or more events comprises classifying the one or more events based at least on a portion of the periodic process.
